(19) United States
(12) Patent Application Publication
(10) Pub. No.: US 2025/0346805 A1
(43) Pub. Date: Nov. 13, 2025

(54) OPTICAL METHOD TO ENHANCE DETECTION VISIBILITY USING BRIGHT EMISSIVE PROBE

(71) Applicant: KLA Corporation, Milpitas, CA (US)

(72) Inventors: Pradeepkumar Jagadesan, San Jose, CA (US); Grace Hsiu-Ling Chen, Los Gatos, CA (US)

(21) Appl. No.: 19/062,941

(22) Filed: Feb. 25, 2025

Related U.S. Application Data
(60) Provisional application No. 63/645,179, filed on May 10, 2024.

(51) Int. Cl. C09K 11/06; C09K 11/02; G01N 21/88; G01N 21/95; H01L 21/67

(52) U.S. Cl. CPC C09K 11/06; C09K 11/025; G01N 21/8806; G01N 21/9501; H01L 21/67288; C09K 2211/1007; C09K 2211/1018; G01N 2201/061

(57) ABSTRACT

A patterned sample is disclosed. The patterned wafer may include a first substrate material and a photoluminescent material configured to bind to the first substrate material to enhance a feature of interest. The photoluminescent material may include a photoluminescent compound comprising a fluorophore and an intermolecular blocking agent configured to hinder quenching of the fluorophore caused by intermolecular interaction with another fluorophore.

### CROSS-REFERENCE TO RELATED APPLICATIONS

The present application claims the benefit under 35 U.S.C. §119(e) of U.S. Provisional Patent Application Ser. No. 63/645,179, filed May 10, 2024, which is incorporated herein by reference in the entirety.

### TECHNICAL FIELD

The present invention generally relates to defect detection and pattern measurements, and, more particularly, to a system and method for selectively enhancing a defect or pattern signal using photoluminescent material.

### BACKGROUND

As the demand for integrated circuits having increasingly small device features continues, the need for improving defect detection mechanisms continues to grow. Current inspection systems rely on principles of light scattering for defect signal generation. However, one disadvantage of using light scattering principles is that defect signal generation is directly proportional to the size of the defect, where the defect signal decreases as the size of the defect shrinks.

Wafer noise induced by process variation is due to at least three factors: (1) higher difficulties in manufacturing shrunken design structures, (2) similar scaling of surface roughness, edge roughness, and edge placement errors that are expected to remain, and (3) noise scattering elements being packed more densely as design structure shrinks. This poses a great challenge for current inspection systems that rely on light scattering principles.

To keep up with the sensitivity demand, fluorescent probes have been developed that can selectively bind aspects of the wafer and strongly emit light when excited. However, when two molecules of a fluorescent dye are placed tightly together, intermolecular interactions may take place, causing a reduction of fluorescence emission to occur, referred to as fluorescence quenching. Because the critical dimension of advanced IC devices is approximately 10 nm, fluorescence probes bound to small IC structures may be closely packed, resulting in quenching that prevents these probes from being effectively used.

As such, it would be advantageous to provide a system and method to remedy the shortcomings of the approaches identified above.

### SUMMARY

In embodiments, an inspection system is disclosed, in accordance with one or more embodiments of the present disclosure. In one or more embodiments, the inspection system includes an illumination source configured to generate one or more illumination beams, a substrate including a first substrate material, and a photoluminescent material configured to bind to the first substrate material to enhance a feature of interest on the substrate. In one or more embodiments, the photoluminescent material includes a photoluminescent compound including a fluorophore, and an intermolecular blocking agent configured to hinder quenching of the fluorophore caused by intermolecular interaction with another fluorophore. In one or more embodiments, the inspection system includes a set of optical elements configured to direct the one or more illumination beams from the illumination source to a surface of the substrate, and one or more detectors configured to detect photoluminescent emission emitted by the photoluminescent material bound to the first substrate material, the set of optical elements configured to direct the photoluminescent emission from the photoluminescent material to the first substrate material to the one or more detectors.

In embodiments, a patterned sample is disclosed, in accordance with one or more embodiments of the disclosure. In one or more embodiments, the patterned sample includes a first substrate material, and a photoluminescent material configured to bind to the first substrate material to enhance a feature of interest. In one or more embodiments, the photoluminescent material includes a photoluminescent compound including a fluorophore, and an intermolecular blocking agent configured to hinder quenching of the fluorophore caused by intermolecular interaction with another fluorophore.

A method for inspecting a substrate is disclosed, in accordance with one or more embodiments of the disclosure. In embodiments, the method includes generating one or more illumination beams using an illumination source. In embodiments, the method includes directing the one or more illumination beams to the substrate using a set of optical elements, the substrate including at least a first substrate material and at least a second substrate material, wherein the first substrate material is different from the second substrate material, the substrate further including a photoluminescent material configured to selectively bind to one of the first substrate material or the second substrate material, wherein the photoluminescent material includes: a photoluminescent compound including a fluorophore; and an intermolecular blocking agent configured to hinder quenching of the fluorophore caused by intermolecular interaction with another fluorophore. In embodiments, the method includes detecting photoluminescent emission emitted preferentially from the photoluminescent material of one of the first substrate material or the second substrate material of the substrate using one or more detectors.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates a simplified schematic of an inspection system including a photoluminescent patterned substrate, in accordance with one or more embodiments of the present disclosure.

FIG. 1B illustrates a conceptual view of a substrate labeled with photoluminescent compounds, in accordance with one or more embodiments of the disclosure and with fluorophores separated with a distance greater than the intermolecular interaction length (denoted as d_{critical})

FIGS. 1C-1D illustrate conceptual views of substrates labeled with photoluminescent compounds such that the fluorophores from the photoluminescent compounds are positioned with distances less than the intermolecular interaction length (d_{critical}) and intermolecular blocking agents configured to hinder fluorescence quenching due to intermolecular interaction, in accordance with one or more embodiments of the disclosure.

FIG. 1E illustrates a conceptual view of a substrate labeled with photoluminescent compounds, each with intermolecular blocking agents, such as a side chain, configured to disrupt intermolecular interactions to preserve fluorescence emission when the photoluminescence probes are closely packed, in accordance with one or more embodiments of the disclosure.

FIG. 2A illustrates a conceptual view of a patterned substrate, in accordance with one or more embodiments of the present disclosure.

FIG. 2B illustrates a conceptual view of a substrate including a defect, in accordance with one or more embodiments of the present disclosure.

FIG. 2C illustrates a conceptual view on an addition of the photoluminescent material, including the intermolecular blocking agent to the substrate, in accordance with one or more embodiments of the disclosure.

FIGS. 2D-2E illustrate conceptual views of a substrate coated with photoluminescent material, including a different form of intermolecular interaction disruption agent, in accordance with one or more embodiments of the disclosure.

FIG. 2F illustrates a fluorescent image depicting quenching of the photoluminescent compound Pacific Blue (3-carboxy-6,8-difluoro-7-hydroxycoumarin), in accordance with one or more embodiments of the disclosure.

FIG. 2G illustrates fluorescent images depicting drops of a free 4-(5-phenyloxazol-2-yl)phenylpropionic acid (DPOA) solution, and a caged DPOA solution, respectively, as well as a graph depicting the intensity of fluorescent emission of the free DPOA solution and caged DPOA solution at a range of wavelengths, in accordance with one or more embodiments of the disclosure. A beta cyclodextrin (b-CD) cage acts as the intermolecular interaction disruption agent, allowing fluorescence emission to recover.

FIG. 3A illustrates a side conceptual view of a patterned substrate, in accordance with one or more embodiments of the present disclosure.

FIG. 3B illustrates an exploded conceptual view of a patterned substrate including one or more photoluminescent materials, in accordance with one or more embodiments of the present disclosure.

FIG. 4A illustrates a side conceptual view of a patterned substrate including a linker molecule and photoluminescent marker molecule, in accordance with one or more embodiments of the present disclosure.

FIG. 4B illustrates a side conceptual view of a patterned substrate including a linker molecule and photoluminescent marker molecule, in accordance with one or more embodiments of the present disclosure.

FIG. 5A illustrates a side conceptual view of a patterned substrate including a self-assembled monolayer linker molecule and photoluminescent marker molecule, in accordance with one or more embodiments of the present disclosure.

FIG. 5B illustrates a simplified schematic of a method of selectively marking a patterned substrate using a self-assembled monolayer linker molecule and photoluminescent marker molecule, in accordance with one or more embodiments of the present disclosure.

FIG. 6 illustrates a flow diagram depicting a method for detecting defects using photoluminescent materials that include an intermolecular blocking agent, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a system and method for enhancing photon emission using a photoluminescent material with features that inhibit quenching of the fluorophore caused by intermolecular interaction with another fluorophore. For example, the photoluminescent material may include a fluorescent fluorophore and an agent that prevents two or more fluorescent fluorophore molecules from coming into close enough contact that quenching occurs. The agent may include molecules that isolate individual fluorescent fluorophores by surrounding them with dummy molecules or caging molecules without quenching the fluorophore. The agent may also include moieties on the fluorescent fluorophore molecule itself that sterically hinder the fluorescent fluorophore from effectively packing (e.g., aggregating) and self-quenching. By utilizing caging compounds, dummy molecules, and/or bulky/charged side-chains, nanometer-scale spaces are created between the dyes to minimize quenching from intermolecular interactions. Note-add wording such as cage, bulky side chain, dummy molecules, and nanometer-scale spacers to the figure description.

The photoluminescent material may also be configured to selectively attach to at least one of a first material or a second material of a substrate, such as those materials found on a patterned semiconductor wafer. For instance, an illumination source may be configured to excite the photoluminescent material of the first material or the second material to cause the photoluminescent material to emit photoluminescent emission. In this regard, the photoluminescent material may be configured to preferentially attach to one of the first material or the second material to enhance the photon emission of a feature of interest (e.g., a defect of interest, a pattern of interest, or a material of interest) formed of at least one of the first material or the second material. The ability of a photoluminescent material to selectively bind a first material or a second material while inhibiting quenching may further increase the ability of the photoluminescent material to illuminate features of interest for detection.

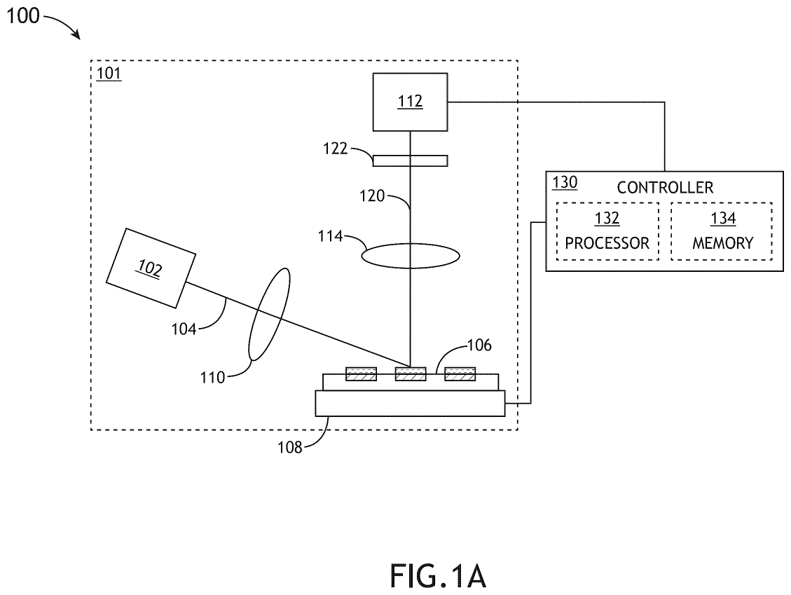

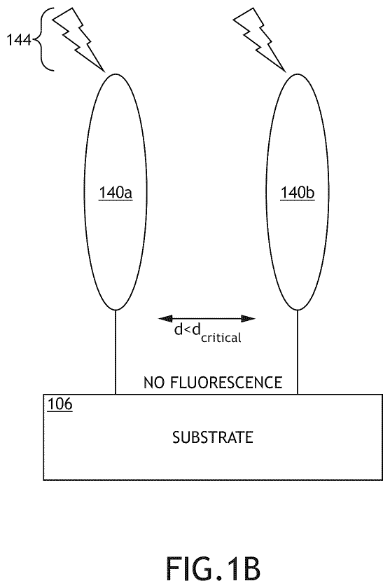

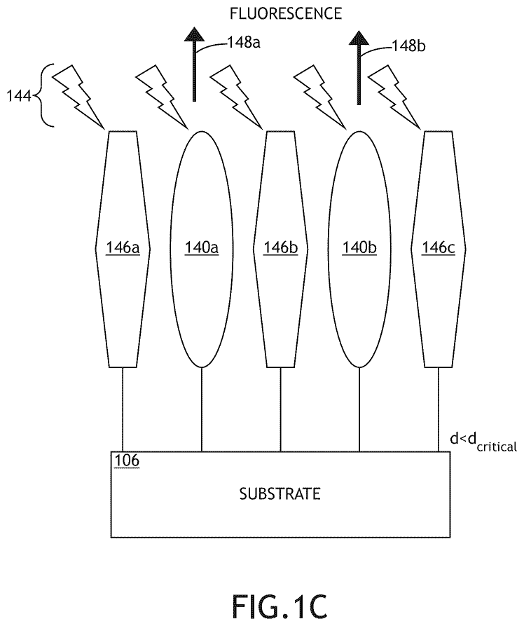

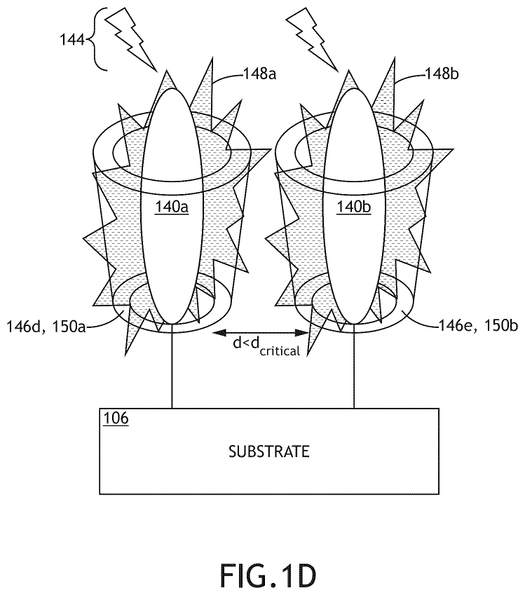

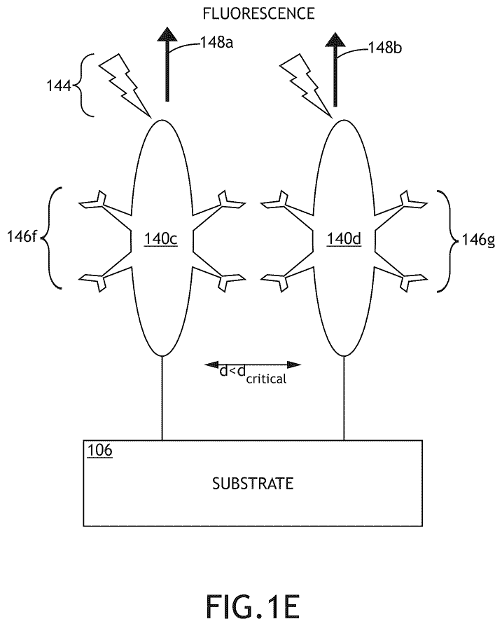

FIG. 1A is a simplified schematic diagram illustrating an inspection system 100, in accordance with one or more embodiments of the present disclosure.

In embodiments, the system 100 may include an illumination source 102 configured to generate one or more illumination beams 104. The illumination source 102 may include any type of illumination source suitable for exciting a photoluminescent material on a surface of a substrate.

In embodiments, the illumination source 102 includes one or more narrowband illumination sources. For example, the illumination source 102 may include, but is not limited to, a laser system, including one or more laser sources, configured to generate a laser beam including illumination of a selected wavelength or range of wavelengths. The laser system may be configured to produce any type of laser radiation such as, but not limited to, infrared radiation, visible radiation, and/or ultraviolet (UV) radiation. By way of another example, the illumination source 102 may include, but is not limited to, one or more light-emitting diodes (LEDs).

In embodiments, the illumination source 102 includes one or more broadband illumination sources. For example, the illumination source 102 may include, but is not limited to, a broadband lamp configured to generate broadband light of a range of wavelengths (e.g., white light). For instance, the illumination source 102 may include, but is not limited to, a broadband plasma (BBP) light.

In embodiments, the system includes one or more optical elements 110 configured to direct or alter the illumination beam 104 to the substrate 106. For example, the one or more optical elements 110 may include one or more spectral filters. For instance, the one or more spectral filters may be configured to maximize excitation of the photoluminescent material (as discussed further herein).

In embodiments, the system 100 includes a stage assembly 108 suitable for securing and positioning the substrate 106. The stage assembly 108 may include any sample stage architecture known in the art. For example, the stage assembly 108 may include a linear stage and/or a rotational stage.

It is noted herein that the inspection system 100 may operate in either an imaging mode or a non-imaging mode. In an imaging mode, individual objects (e.g., defects) are resolvable within the illuminated spot on the sample. In a non-imaging mode of operation, all of the light collected by one or more detectors is associated with the illuminated spot on the sample.

In embodiments, the system 100 includes one or more collection optics 114 configured to collect photoluminescent emission 120 emitted from the substrate 106 and direct the photoluminescent emission 120 to one or more detectors 112. It is noted herein that one or more collection optics 114 may be oriented in any position relative to the substrate 106. The one or more collection optics 114 may include an objective lens oriented normally to the substrate 106. The one or more collection optics 114 may further include a plurality of collection lenses oriented normal to photoluminescent emission 120 from multiple solid angles.

In embodiments, the one or more optical elements 122 are configured to condition the photoluminescent emission 120 prior to detection by the one or more detectors 112. The one or more optical elements 122 may include any elements known in the art suitable for conditioning the photoluminescent emission 120 including, but not limited to, one or more diffractive elements, one or more refractive elements, one or more beam splitters, one or more polarizers, one or more wavelength-selective filters, or one or more neutral density filters.

In embodiments, the one or more optical elements 122 include one or more wavelength-selective filters suitable for passing fluorescent emission corresponding to the emission spectra of one or more photoluminescent materials while blocking wavelengths associated with the illumination beam 104. The one or more optical elements 122 may further separate photoluminescent illumination from one or more distinct emission spectra associated with one or more photoluminescent materials such that each distinct emission spectra is directed to a separate detector 112. In embodiments, the one or more optical elements 122 may include a diffraction grating configured to physically separate wavelengths associated with the illumination beam 104 from one or more wavelengths associated with the emission spectra of one or more photoluminescent materials. Further, it is noted herein that the detector 112 may include any optical detector known in the art suitable for measuring light emerging from the substrate 106. For example, the detector 112 may include, but is not limited to, a CCD detector, a TDI detector, a photomultiplier tube (PMT), an avalanche photodiode (APD), or the like.

It is noted herein that the one or more optical elements 110 and the one or more collection optics 114 may be referred to as a single set of optical elements. It is further noted that the one or more optical elements 110 and the one or more collection optics 114 may share common optical elements. For example, a single objective lens may be configured to both direct illumination to the sample and collect returned light from the sample.

In embodiments, the system 100 includes a controller 130 communicatively coupled to the one or more detectors 112. The controller 130 may include one or more processors 132 configured to execute a set of program instructions maintained in a memory medium or memory 134.

In embodiments, the one or more processors 132 are configured to execute program instructions configured to direct the one or more processors 132 to identify one of more defects 204 on the substrate 106 based on the collected photoluminescent emission 120. For example, the one or more processors 132 may be configured to generate a defect map of the surface of the substrate 106 including one or more identified defects 204. In embodiments, the controller 130 is further communicatively coupled to the stage assembly 108 to associate photoluminescent emission 120 with specific locations on the sample associated with one or more defects 204.

FIG. 1B illustrates a conceptual view of a substrate 106 labeled with photoluminescent compounds 140a, 140b, in accordance with one or more embodiments of the disclosure. The photoluminescent compounds 140a, 140b are able to attach to a surface of the substrate 106 via a direct interaction between the surface of the substrate and the photoluminescent compounds 140a, 140b, or via a linker molecule that links the substrate 106 to the photoluminescent compounds 140a, 140b. The photoluminescent compounds 140a, 140b may be attached to the substrate 106 at less than a critical quench distance (e.g., d_{critical}) to each other (e.g., the fluorophores may be separated by a distance greater than the intermolecular interaction length). The critical quench distance refers to the minimal distance that two photoluminescent compounds 140a, 140b can be spaced from each other without causing quenching due to intermolecular interaction. For example, and as shown in FIG. 1B, the two photoluminescent compounds 140a, 140b are attached to the substrate 106, with a distance, d, between the two photoluminescent compounds 140a, 140b that is less than a critical quench distance, d_{critical}. Because of this, when the photoluminescent compounds 140a, 140b receive an excitation light 144, quenching occurs, resulting in a reduction of emitted fluorescence.

FIG. 1C-1D illustrate conceptual views of a substrate 106 labeled with photoluminescent compounds 140a, 140b, such that the fluorophores from the photoluminescent compounds are positioned with distances less than the intermolecular interaction length (d_{critical}) and intermolecular blocking agents 146a, 146b, 146c configured to hinder fluorescence quenching of the photoluminescent compounds 140a, 140b due to intermolecular interaction, in accordance with one or more embodiments of the disclosure. The intermolecular blocking agents 146a, 146b, 146c may include any molecules or moieties that are photochemically inactive to the excitation light 144 used to excite the fluorophore of the photoluminescent compounds 140a, 140b. In this manner the intermolecular blocking agents 146a, 146b, 146c act as photochemically inactive dummy molecules that reduce quenching of the photoluminescent compounds 140a, 140, allowing the photoluminescent compounds 140a, 140b to emit a fluorescent light 148a-b detectable by the one or more detectors 112. The intermolecular blocking agents 146a, 146b, 146c may bind to the substrate 106 and/or photoluminescent compounds 140a, 140b via any type of molecular interaction including, but not limited to, covalent bonding, ionic bonding, hydrogen bonding, hydrophobic interactions, ion-dipole interactions, and interactions involving Van der Waals forces.

In embodiments, the intermolecular blocking agents 146a, 146b, 146c reduce quenching by one or more modes of action. For example, the intermolecular blocking agents 146a, 146b, 146c may reduce quenching by forming a layer around the photoluminescent compounds 140a, 140b that hinders (e.g., sterically hinders) the fluorophores of the photoluminescent compounds 140a, 140b from packing or aggregating, keeping the distance between fluorophores beyond the critical quench distance. For instance, the intermolecular blocking agents 146a, 146b, 146c may include large molecules such as cyclodextrin or dendrimers that bind and isolate the fluorophores. Other intermolecular blocking agents 146a, 146b, 146c may include noncaging intermolecular blocking agents 146a, 146b, 146c such as surfactants, including, but not limited to, cetyltrimethylammonium bromide (CTAB).

As shown in FIG. 1D, the intermolecular blocking agents 146d, 146e, may encapsulate or cage individual photoluminescent compounds 140a, 140b in molecular cages 150a, 150b (e.g., supramolecular cages), preventing interaction between individual fluorophores. The cages 150a, 150b act as a wall between the adjacent dyes and reduce interaction between fluorophores.

Encapsulating and/or caging molecules may include, but are not limited to, nanoparticles (e.g., silica, polymeric, or carbon-based nanoparticles) catenanes, rotaxanes, nanocarriers, coordination cages, metal-organic frameworks, cucurbituril, calixarene, and the aforementioned cyclodextrin and dendrimers. In another example, the intermolecular blocking agents 146a, 146b, 146c may include crosslinking agents and/or polymer matrices that stabilize individual photoluminescent compounds 140a, 140b including, but not limited to polystyrene and polyethylene glycol.

FIG. 1E illustrates a conceptual view of a substrate 106 labeled with photoluminescent compounds 140c, 140d, each including intermolecular blocking agents 146f, 146g, such as side chains, configured to disrupt intermolecular interactions to preserve fluorescence emission when the photoluminescent compounds 140c, 140d are closely packed, in accordance with one or more embodiments of the disclosure. For example, the intermolecular blocking agents 146f, 146g may include side chains of the photoluminescent compounds 140c, 140d having bulky or ionic functional groups that sterically hinder or repel adjacent photoluminescent compounds 140c, 140d, keeping fluorophores from packing or aggregating within the critical quench distance. Bulky groups may include carbon-based groups (e.g., alkyl groups/chains, alkene groups/chains, or alkyne groups/chains) such as methyl groups, ethyl groups, or higher number n-groups. Ionic groups may include, but not be limited to, quaternary ammonium, sulphonate, and phosphonate. Side chains of the photoluminescent compounds 140c, 140d that include these intermolecular blocking moieties may reduce or prevent the quenching via electrostatic repulsion further to obtain 100% fluorescence of the photoluminescent compounds 140c, 140d.

In another example, the intermolecular blocking agents 146f, 146g may include moieties and/or molecular structures that add length to aspects of the photoluminescent compounds 140c, 140d without disrupting fluorophore functionality. In another example, the intermolecular blocking agents 146f, 146g may include non-planar structures and/or moieties that disrupt TT-TT stacking interactions, reducing packing or aggregation.

In embodiments, the intermolecular blocking agents 146a, 146b, may include molecules that prevent quenching and/or promote increased fluorescence upon packing or aggregation (e.g., aggregation-induced emission (AIE) compounds). For example, the intermolecular blocking agents 146a, 146b may include tetraphenylethene (TPE) or other AIE compounds.

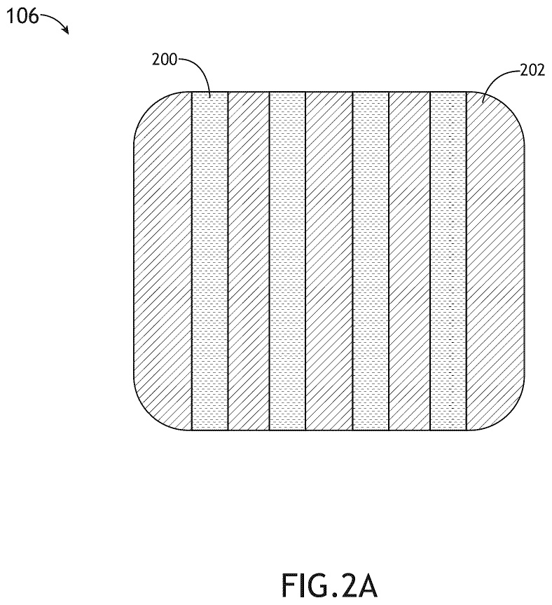

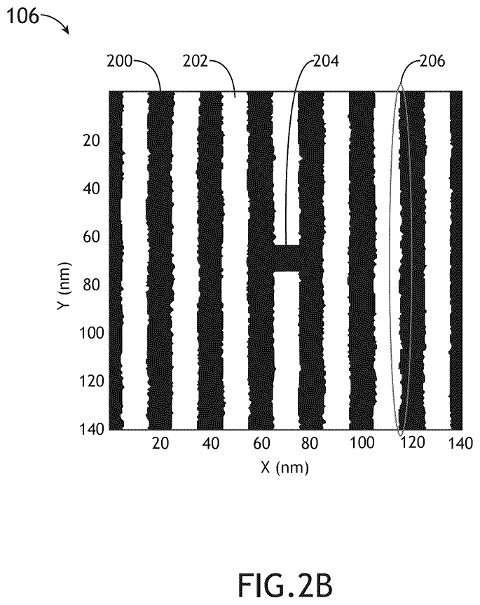

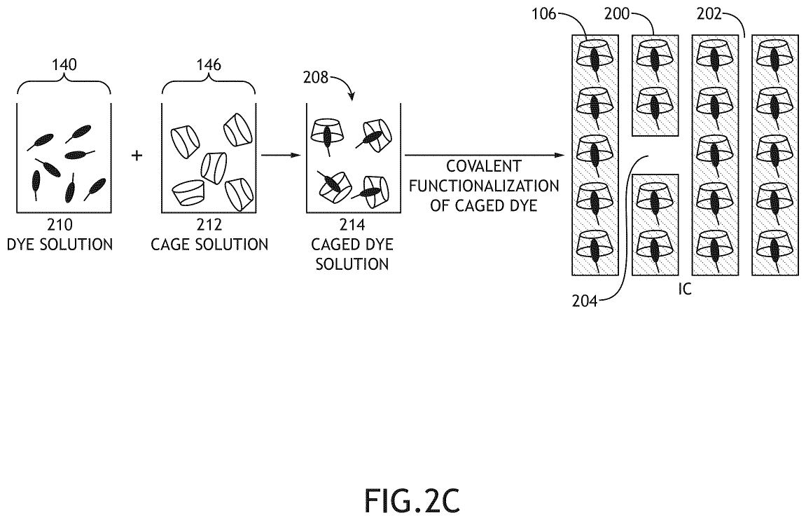

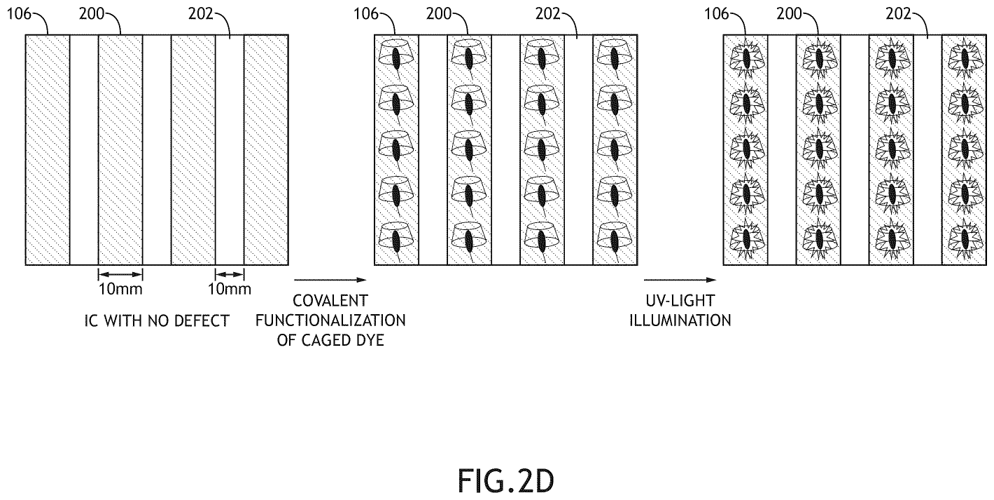

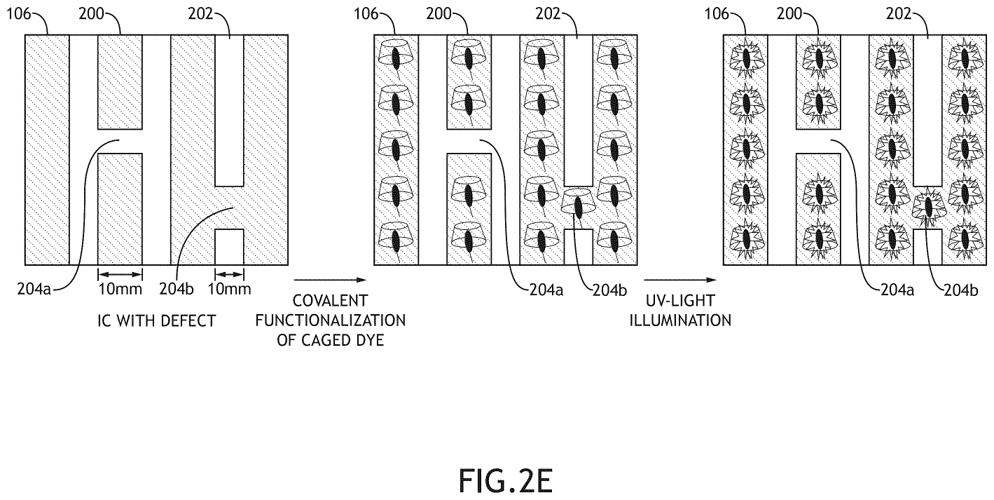

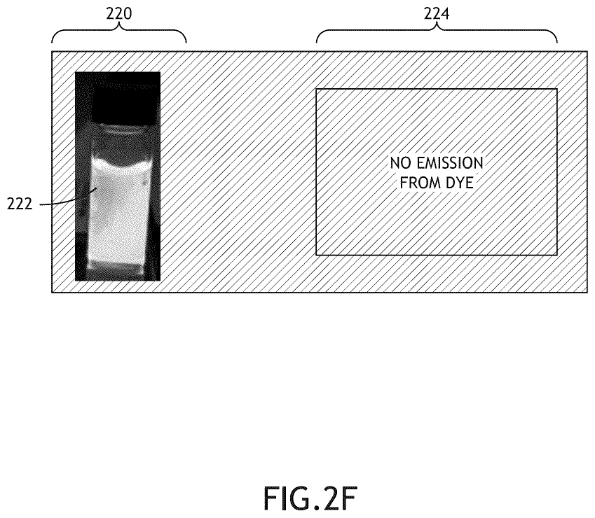

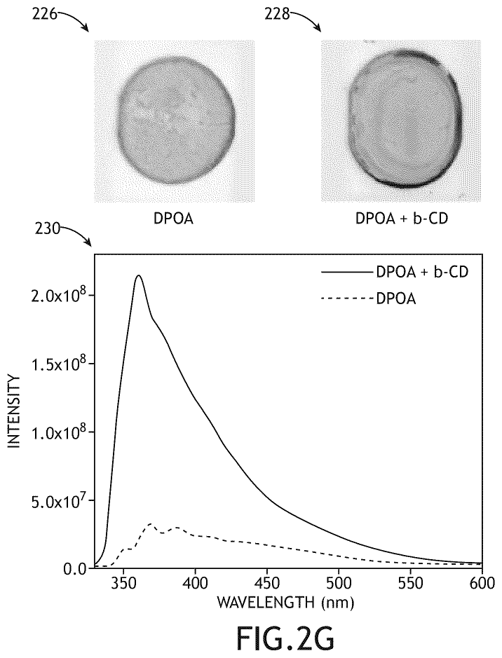

Referring to FIGS. 2A-2E, in embodiments, the substrate 106 may include a patterned substrate 106. For example, the substrate 106 may include a patterned wafer. For instance, the substrate 106 may include an integrated circuit (IC) device. It is noted herein that the patterned substrates 106 illustrated in FIGS. 2A-2E are shown at a high magnification for illustrative purposes.

The pattern of the substrate 106 may be formed of at least a first material 200, and a second material 202, where the first material 200 is different from the second material 202. For example, as shown in FIGS. 2A-2B, the substrate 106 may include a grating pattern formed from the interlacing of the first material 200 and the second material 202.

Although FIGS. 2A-2B depict the patterned substrate 106 being formed of a first material 200 and a second material 202, it is noted that the patterned substrate 106 may be formed of any number of materials. For example, the patterned substrate 106 may be formed of at least a first material, a second material, a third material . . . up to an Nth number of materials.

In embodiments, the first material or the second material may include, but is not required to include, porous carbon doped organosilicon (pSiCOH), copper (Cu), cobalt (Co), ruthenium (Ru), tungsten (W), aluminum (Al), silicon (Si), polycrystalline silicon, titanium nitride (TiN), silicon nitride (Si3N4), and the like.

Referring to FIG. 2B, the substrate 106 may include a defect 204 positioned between a portion of the first material 200 and a portion of the second material 202. For example, the substrate 106 may include a bridge defect 204 positioned between a portion of the first material 200 and a portion of the second material 202. For instance, the bridge defect 204 may be a 10 nm bridge defect, where the critical dimension of the line and space array is 10 nm. Further, the substrate 106 may include edge noise 206 caused by line edge roughness and edge placement error (approximately 1-2 nm noise level for both).

In embodiments, the substrate 106 may include one or more photoluminescent materials 208 (e.g., containing the photoluminescent compounds 140 and the intermolecular blocking agent 146) configured to selectively bind to one of the first material 200 or the second material 202 to enhance a feature of interest on the substrate 106, as shown in FIG. 2C. For example, the one or more photoluminescent materials 208 may be configured to preferentially attach to a targeted material (e.g., the first material 200 or the second material 202) to enable the targeted material to have enhanced photon emission based on the properties of the photoluminescent material 208. In one instance, the one or more photoluminescent materials 208 may be configured to preferentially attach to the first material 200 and not the second material 202, such that only the signal from the first material 200 is enhanced. In another instance, the one or more photoluminescent materials 208 may be configured to preferentially attach to the second material 202 and not the first material 200, such that only the signal from the second material 202 is enhanced.

The one or more photoluminescent materials 208 may include one or more photoluminescent molecules including, but not limited to, one or more organic dyes (e.g., Cy5, Cy3, rhodamine, or the like), one or more quantum dots (e.g., cadmium telluride (CdTe) dots, cadmium sulfide (CdS) dots, zinc sulfide (ZnS) dots, or the like), one or more carbon dots, one or more transition metals, or one or more conjugated polymers (e.g., polypyrrole, polythiophene, or the like). Other photoluminescent materials 208 include, but are not limited to, 4-(5-phenyloxazol-2-yl)phenylpropionic acid (DPOA), 2,5-diphenyloxazole (PPO), p-terphenyl, carbostyril 124, pacific blue 3-carboxy-6,8-difluoro-7-hydroxycoumarin, or a pentiptycene-based dye.

For purposes of the present disclosure, it is noted that a feature of interest may include, but is not limited to, a defect of interest, a pattern of interest, or a material of interest. For example, the one or more photoluminescent materials 208 may be configured to selectively bind to one of the first material 200 or the second material 202 to enhance a defect of interest. By way of another example, the one or more photoluminescent materials 208 may be configured to selectively bind to one of the first material 200 or the second material 202 to enhance a pattern of interest. By way of another example, the one or more photoluminescent materials 208 may be configured to selectively bind to one of the first material 200 or the second material 202 to enhance a material of interest.

FIG. 2C illustrates a conceptual view on an addition of photoluminescent material 208 containing caged photoluminescent compounds 140 to the substrate 106, in accordance with one or more embodiments of the disclosure. Chemical caging is established by mixing a water-soluble supramolecular host and an insoluble/sparingly water-soluble guest molecule (e.g., photoluminescent compounds 140) in aqueous medium. Caging is driven by noncovalent interactions between the photoluminescent compounds 140 and the inner cavity of the cage and hydrophobicity of the photoluminescent compounds 140. Caging introduces a passive wall between the adjacent photoluminescent molecules, which restricts fluorophore interactions to avoid fluorescence quenching. For example, a dye solution 210 that includes photoluminescent compounds 140 may be added to a solution of intermolecular blocking agents 146 (e.g., a cage solution 212), resulting in a photoluminescent material 208 (e.g., a caged dye solution 214) that resists quenching caused by intermolecular packing. When added to the surface of the substrate 106, the photoluminescent material 208 may selectively bind to the first material 200.

FIGS. 2D-2E illustrate conceptual views of a substrate 106 coated with photoluminescent material 208, including a different form of intermolecular interaction disruption agent, in accordance with one or more embodiments of the disclosure. For example, in FIG. 2D a substrate 106 (e.g., an integrated circuit (IC)) with no defects is coated with a photoluminescent material 208 that selectively binds the first material 200. Upon excitation (e.g., via UV-light illumination), the fluorophores of the photoluminescent material 208 emit light, with the intermolecular blocking agent of the photoluminescent material 208 reducing quenching. In another example, in FIG. 2E a substrate 106 with multiple defects 204a, 204b is coated with a photoluminescent material 208 that selectively binds the first material 200. Upon excitation (e.g., via UV-light illumination), the fluorophores of the photoluminescent material 208 emit light, which enhances the detection of the multiple defects 204a, 204b.

FIG. 2F illustrates a fluorescent image depicting quenching of the photoluminescent compound Pacific Blue (3-carboxy-6,8-difluoro-7-hydroxycoumarin), in accordance with one or more embodiments of the disclosure. Two samples containing Pacific Blue were tested for quenching caused by intermolecular packing. A first sample 220 included a vial 222 containing a Pacific Blue solution that has been diluted so that the average distance between individual fluorophore molecules is greater than the critical quench distance. A second sample 224 includes a Si0₂ substrate 106 that has been layered with a high-density coating of Pacific Blue where the fluorophores are packed tightly and the average distance between individual fluorophore molecules is less than the critical quench distance. As shown in FIG. 2F, while the solution of the first sample 220 fluoresces brightly, the substrate 106 of the second sample 224 does not and is therefore not visible in the fluorescent image. Therefore, Pacific Blue Dye emits strong emission when it is in the solution (e.g., a not-closely packed formation) but exhibits no emission once it is closely packed on the substrate.

FIG. 2G illustrates fluorescent images 226, 228 depicting drops of a free 4-(5-phenyloxazol-2-yl)phenylpropionic acid (DPOA) solution, and a caged DPOA solution, respectively, as well as a graph 230 depicting the intensity of fluorescent emission of the free DPOA solution and caged DPOA solution at a range of wavelengths, in accordance with one or more embodiments of the disclosure. The caged DPOA solution includes b-cyclodextrin (b-CD) molecules, an intermolecular blocking agent 146, that “cages” the DPOA molecules, preventing the DPOA molecules from coming within a critical quench distance from each other. As shown in graph 230, the effect of the b-CD molecules enhances the emission of the DPOA fluorophore several-fold in a range between 350 nm and 450 nm.

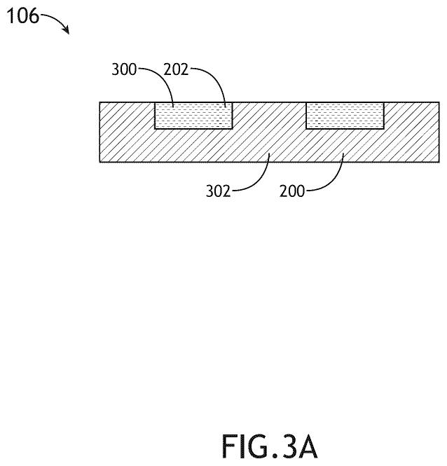

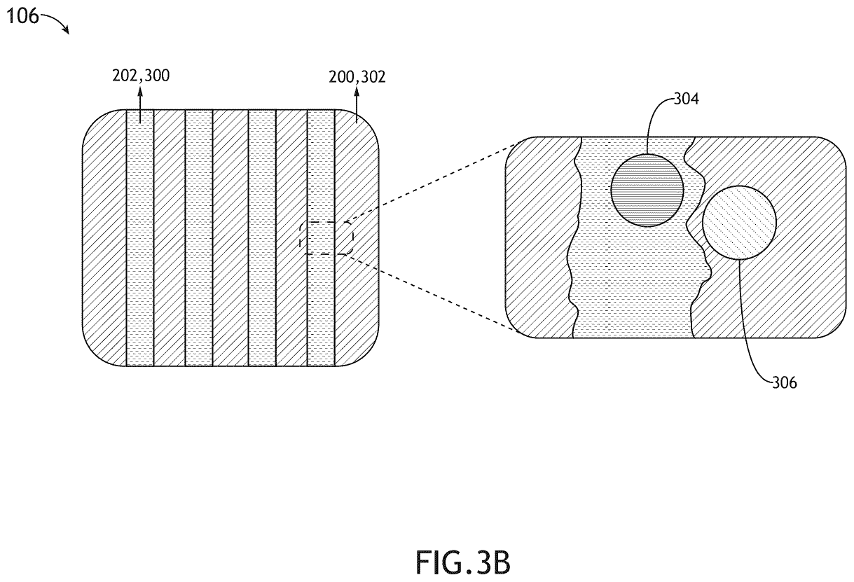

Referring to FIGS. 3A-3B, in embodiments, the photoluminescent material 208 may include a hydrophobic fluorophore (e.g., Cy5). For example, the first material 200 may include a low k dielectric material 302 (e.g., porous organosilicon) and the second material 202 may include a metal 300 (e.g., Cu, W, Co, Ru, Al, and the like). For instance,, the hydrophobic fluorophore 304 (e.g., Cy5) may be configured to fluorescently label the low k dielectric material 302 (e.g., porous organosilicon). In this regard, the hydrophobic fluorophore 304 (e.g., Cy5) may be configured to preferentially attach to a hydrophobic surface such as a low k dielectric surface, such that selectivity is achieved. It is noted that hydrophobic fluorophores, such as Cy5, may be configured to selectively tether to the low-k dielectric surface (e.g., as shown in FIG. 3A-3B) and produce bright fluorescence emission while no emission may be observed from the metal patterns due to metal-induced fluorescent quenching. For example, it is noted that the hydrophobic fluorophore may incidentally attach 306 to the hydrophilic metal surface of the metal 300, however, the metal surface may not fluoresce due to metal-induced fluorescent quenching.

In embodiments, the photoluminescent material 208 includes a linker molecule and a marker molecule. The linker molecule may be configured to enable a preferential material connection between the substrate and the marker molecule, where the marker molecule may be configured to selectively mark a targeted material to enable amplification of a feature of interest signal (e.g., defect of interest, pattern of interest, or material of interest). The linker molecule may include, but is not required to include, one of polydopamine (pDA), polynorepinephrine (pNE), self-assembled monolayer (SAM), or the like. In this embodiment, the selectivity may be controlled by the linker material.

It is noted herein that the linker molecule may be used to functionally and/or physically separate the photoluminescent molecule from the material of the substrate to maximize the efficiency of the photoluminescent properties of the photoluminescent molecule. The length of the linker molecule may be adjusted to balance the physical separation of a luminescent molecule from other molecules that may induce quenching of the photoluminescent output.

A photoluminescent marker (or photoluminescent molecule) in an inspection system 100 may include any type of photoluminescent particle suitable for generating photoluminescence. For example, the one or more photoluminescent tags may include one or more fluorescent tags. For instance, the signal molecule may include one or more hydrophobic fluorophores, one or more hydrophilic fluorophores, and the like. It is noted that the description of fluorescence in the present disclosure is intended to be illustrative rather than limiting and that the detection of defects using any type of photoluminescent material is within the scope of the present disclosure.

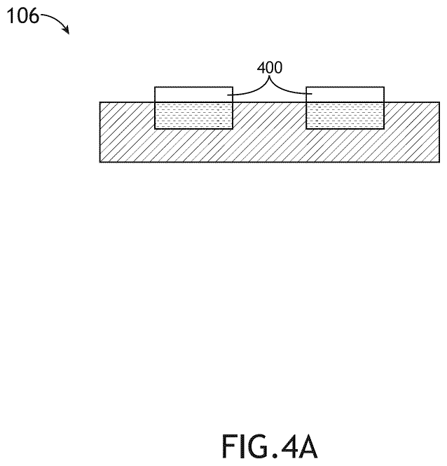

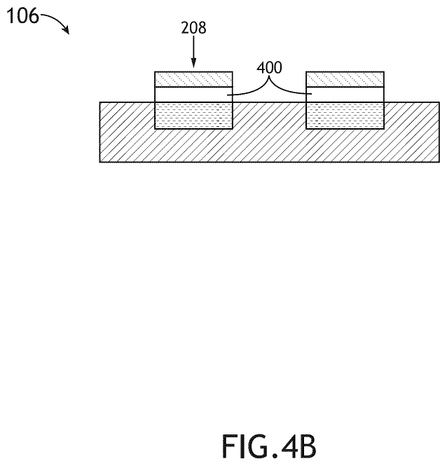

Referring to FIGS. 4A-4B, in a non-limiting example, the linker molecule 400 may include one of pDA or pNE. For example, one of the first material 200 or the second material 202 may be coated with one of pDA or pNE. For instance, the first material 200 may include a metal material, where the metal material may be coated with one of pDA or pNE. In embodiments, one or more fluorophores may be incorporated into the coating. For example, the one or more fluorophores may be co-polymerized with pDA or pNE to selectively mark the metal structure. In alternative embodiments, the one or more fluorophores may be configured to selectively attach to the pDA or pNE surface after the metal surface is coated.

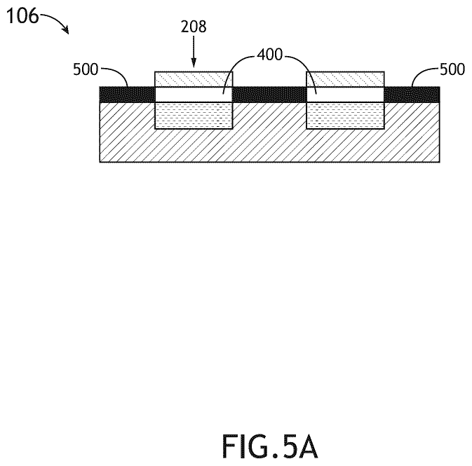

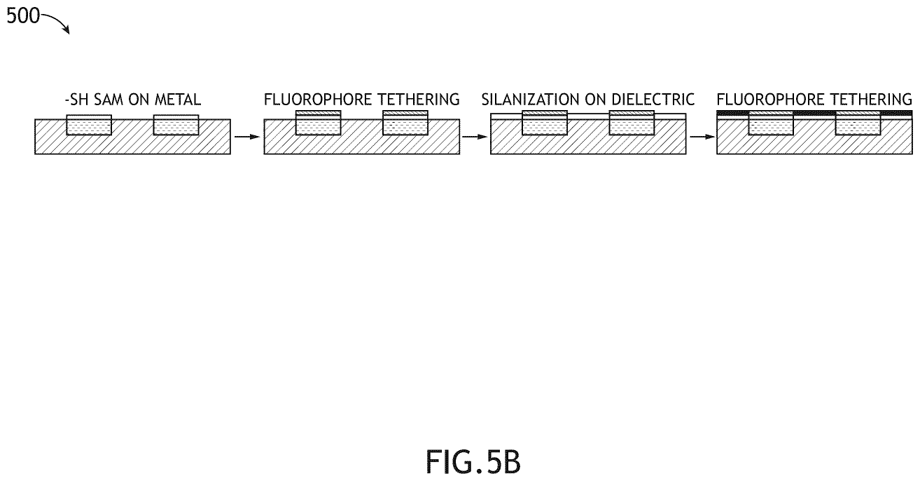

Referring to FIGS. 5A-5B, in embodiments, the linker molecule 400 may include a SAM 500. For example, the first material 200 may include a low dielectric constant material and the second material 202 may include a metal, where surface modification of the low dielectric constant material via hydrolysis followed by silanization with the addition of trichloro-alkyl silane compounds or other similar substances (such as trimethoxy-silane, triethoxy-silane) may form SAM 500 on the low dielectric material. Selective marking of the metal may be achieved by tethering one or more fluorophores on thiol-like molecules or phosphonate molecules on metals with one or more additional fluorophores on the SAM 500.

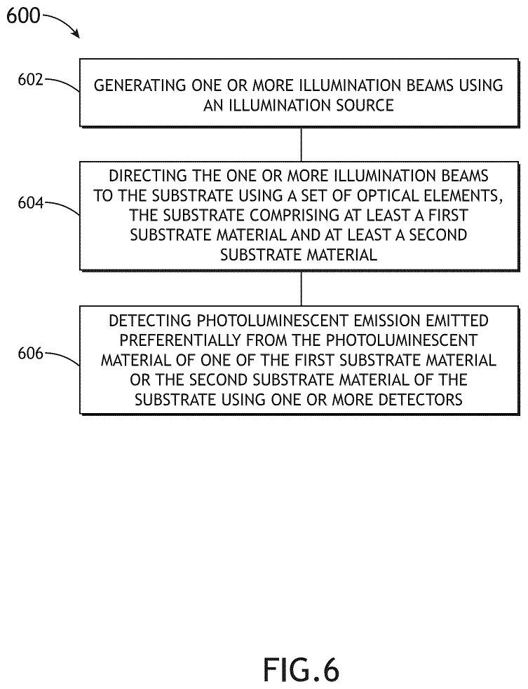

FIG. 6 illustrates a flow diagram depicting a method 600 to detect defects using photoluminescent materials that include an intermolecular blocking agent, in accordance with one or more embodiments of the present disclosure. The method 600 may be utilized by the system 100 as described herein.

In embodiments, the method 600 includes a step 602 of generating one or more illumination beams using an illumination so. For example, the illumination source 102 may be configured to generate one or more illumination beams 104. In embodiments, the illumination source 102 may be configured to excite the photoluminescent material 208 on one of the first material 200 or the second material 202.

In a step 604, directing the one or more illumination beams to the substrate 106 using a set of optical elements, the substrate 106 comprising at least a first substrate material 200 and at least a second substrate material 202, wherein the first substrate material 200 is different from the second substrate material 202, the substrate 106 further comprising a photoluminescent material 208 configured to selectively bind to one of the first substrate material 200 or the second substrate material 202, wherein the photoluminescent material comprises: a photoluminescent compound 140 comprising a fluorophore; and an intermolecular blocking agent 146 configured to hinder quenching of the fluorophore caused by intermolecular interaction with another fluorophore.

In a step 606, the emitted photoluminescent light may be detected. For example, the one or more detectors 112 may be configured to detect the photoluminescent emission 120 from the photoluminescent material 208. Upon detection, one or more defects 204 may be identified based on the detected photoluminescent emission. For example, the one or more defects 204 may be identified by generating a defect map of the surface of the substrate 106 on which the one or more identified defects 204 are identified.

Although embodiments of the present disclosure are directed to an inspection system, it is contemplated that the patterned wafer including the selectively bounded photoluminescent material may be used with any characterization system including, but not limited to, an optical metrology system (e.g., image-based metrology system), or the like.

It is further contemplated that each of the embodiments of the method described above may include any other step(s) of any other method(s) described herein. In addition, each of the embodiments of the method described above may be performed by any of the systems described herein.

In embodiments, the photoluminescent material 208 may have a photoluminescent emission time scale less than or equal to 10 nanoseconds (ns). For example, the photoluminescent material 208 may have a photoluminescent emission time scale between 2 ns and 10 ns. In this regard, the signal of the photoluminescent material 208 may be substantially enhanced. It is noted herein that the photoluminescent material may emit significantly more photons than photon generation through scattering, as discussed previously herein. For example, in a non-limiting example, a fluorophore with a lifetime of 10 ns can generate 105 photons in 1 millisecond (ms), which is much higher than traditional light interaction via scattering. As such, the signal may be enhanced.

In embodiments, the photoluminescent material 208 may have a spatial characteristic length between 2 nanometers and 4 nanometers (nm). For example, in a non-limiting example, the edge noise due to the line roughness and edge displacement may be approximately 1-2 nm, such that the spatial characteristic length of 2-4 nm may serve as a spatial filter to reduce the sensitivity to the presence of edge roughness and edge placement error. In this regard, the roughness and edge placement error may be selectively desensitized, thereby reducing noise.

In embodiments, the photoluminescent material 208 may be configured to selectively bind at the surface level of one of the first material or the second material. In this regard, the noise from the stack and previous layers may be minimized.

In embodiments, the photoluminescent material 208 may have a quantum yield greater than 15 percent. For example, the photon conversion between the absorbed light (for photoluminescence excitation) and emission light may have a quantum yield of 40 percent.

In embodiments, the size of the photoluminescent compounds 140 may be between 2 nm and 4 nm. For example, the size of the photoluminescent compounds 140 may be 3 nm.

Referring again to FIG. 1A, the one or more processors 132 of the controller 130 may include any processing element known in the art. In this sense, the one or more processors 132 may include any microprocessor-type device configured to execute algorithms and/or instructions. In one embodiment, the one or more processors 132 may consist of a desktop computer, mainframe computer system, workstation, image computer, parallel processor, or any other computer system (e.g., networked computer) configured to execute a program configured to operate the system 100, as described throughout the present disclosure. It is further recognized that the term “processor” may be broadly defined to encompass any device having one or more processing elements, which execute program instructions from a non-transitory memory 134. Therefore, the above description should not be interpreted as a limitation on the present invention but merely an illustration.

The memory 134 may include any storage medium known in the art suitable for storing program instructions executable by the associated one or more processors 132. By way of a non-limiting example, the memory 134 may include a non-transitory memory medium. By way of additional non-limiting examples, the memory 134 may include, but is not limited to, a read-only memory, a random access memory, a magnetic or optical memory device (e.g., disk), a magnetic tape, a solid state drive, and the like. It is further noted that memory 134 may be housed in a common controller housing with the one or more processors 132. In an alternative embodiment, the memory 134 may be located remotely with respect to the physical location of the one or more processors 132 and controller 130. For instance, the one or more processors 132 of the controller 130 may access a remote memory (e.g., server), accessible through a network (e.g., internet, intranet, and the like).

For defect inspection of advanced node IC devices, shorter wavelength inspection platforms such as (120 nm-190 nm) platforms or 13 nm platforms are needed. The light source and sustainable optics in the shorter wavelength platforms (120-190 nm) currently do not exist to support inspection throughput demand, and 13 nm system may be too costly to support optical inspection cost targets. The fluorescent system described in this invention has a strong optical emission which can be used to enhance defect signal significantly. The optical emission spectrum of the fluorescent system may be within the wavelength range of 260 nm to 800 nm. This bright fluorescent probe of this system offers a path to enable current and future platforms to provide sensitivity required for future IC design nodes.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for the sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include, but not be limited to, systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include, but not be limited to, systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An inspection system comprising:
an illumination source configured to generate one or more illumination beams;
a set of optical elements configured to direct the one or more illumination beams from the illumination source to a surface of a substrate, wherein the substrate comprises:
a first substrate material;
a photoluminescent material configured to bind to the first substrate material to enhance a feature of interest on the substrate comprising:
a photoluminescent compound comprising a fluorophore; and
an intermolecular blocking agent configured to hinder quenching of the fluorophore caused by intermolecular interaction with another fluorophore; and
one or more detectors configured to detect photoluminescent emission emitted by the photoluminescent material bound to the first substrate material, the set of optical elements configured to direct the photoluminescent emission from the photoluminescent material to the first substrate material to the one or more detectors.

2. The inspection system of claim 1, wherein the substrate comprises a second substrate material, wherein the first substrate material is different from the second substrate material, wherein the photoluminescent material is configured to bind selectively to the first substrate material.

3. The inspection system of claim 1, wherein the intermolecular blocking agent comprises at least one of an intermolecular blocking compound or an intermolecular blocking moiety linked to the photoluminescent compound.

4. The inspection system of claim 3, wherein the photoluminescent material comprises the intermolecular blocking moiety of the photoluminescent compound, wherein the intermolecular blocking moiety comprises at least one of an alkyl chain or a polar group.

5. The inspection system of claim 3, wherein the photoluminescent material comprises a caged intermolecular blocking compound, wherein the caged intermolecular blocking compound comprises at least one of a catenane, a rotaxane, a dendrimer, a nanocarrier, a coordination cage, a metal-organic framework, or a cyclodextrin.

6. The inspection system of claim 5, wherein the caged intermolecular blocking compound comprises cyclodextrin.

7. The inspection system of claim 1, wherein the substrate comprises a semiconductor wafer.

8. The inspection system of claim 6, wherein the photoluminescent compound comprises 4-(5-phenyloxazol-2-yl)phenylpropionic acid (DPOA).

9. The inspection system of claim 3, wherein the photoluminescent material comprises a noncaging intermolecular blocking compound, wherein the noncaging intermolecular blocking compound comprises a surfactant.

10. The inspection system of claim 1, wherein the photoluminescent compound comprises at least one of 4-(5-phenyloxazol-2-yl)phenylpropionic acid (DPOA), 2,5-diphenyloxazole (PPO), p-terphenyl, carbostyril 124, pacific blue 3-carboxy-6,8-difluoro-7-hydroxycoumarin, or a pentiptycene-based dye.

11. A patterned sample comprising:
a first substrate material; and
a photoluminescent material configured to bind to the first substrate material to enhance a feature of interest comprising:
a photoluminescent compound comprising a fluorophore; and
an intermolecular blocking agent configured to hinder quenching of the fluorophore caused by intermolecular interaction with another fluorophore.

12. The patterned sample of claim 11, further comprising a second substrate material, wherein the first substrate material is different from the second substrate material, wherein the photoluminescent material is configured to bind selectively to the first substrate material.

13. The patterned sample of claim 11, wherein the intermolecular blocking agent comprises at least one of an intermolecular blocking compound or an intermolecular blocking moiety linked to the photoluminescent compound.

14. The patterned sample of claim 13, wherein the photoluminescent material comprises the intermolecular blocking moiety of the photoluminescent compound, wherein the intermolecular blocking moiety comprises at least one of an alkyl chain or a polar group.

15. The patterned sample of claim 13, wherein the photoluminescent material comprises a caged intermolecular blocking compound, wherein the caged intermolecular blocking compound comprises at least one of a catenane, a rotaxane, a dendrimer, a nanocarrier, a coordination cage, a metal-organic framework, or a cyclodextrin.

16. The patterned sample of claim 15, wherein the caged intermolecular blocking compound comprises the cyclodextrin.

17. The patterned sample of claim 11, wherein the patterned sample comprises a semiconductor wafer.

18. The patterned sample of claim 13, wherein the photoluminescent compound comprises 4-(5-phenyloxazol-2-yl)phenylpropionic acid (DPOA).

19. The patterned sample of claim 13, wherein the photoluminescent material comprises a noncaging intermolecular blocking compound, wherein the noncaging intermolecular blocking compound comprises a surfactant.

20. The patterned sample of claim 11, wherein the photoluminescent compound comprises at least one of 4-(5-phenyloxazol-2-yl)phenylpropionic acid (DPOA), 2,5-diphenyloxazole (PPO), p-terphenyl, carbostyril 124, pacific blue 3-carboxy-6,8-difluoro-7-hydroxycoumarin, or a pentiptycene-based dye.

21. A method for inspecting a substrate comprising:
generating one or more illumination beams using an illumination source;
directing the one or more illumination beams to a substrate using a set of optical elements, the substrate comprising at least a first substrate material and at least a second substrate material, wherein the first substrate material is different from the second substrate material, the substrate further comprising a photoluminescent material configured to selectively bind to one of the first substrate material or the second substrate material, wherein the photoluminescent material comprises:
a photoluminescent compound comprising a fluorophore; and
an intermolecular blocking agent configured to hinder quenching of the fluorophore caused by intermolecular interaction with another fluorophore; and
detecting photoluminescent emission emitted preferentially from the photoluminescent material of one of the first substrate material or the second substrate material of the substrate using one or more detectors.

22. The method of claim 21, wherein the intermolecular blocking agent comprises at least one of an intermolecular blocking compound or an intermolecular blocking moiety linked to the photoluminescent compound.

23. The method of claim 22, wherein the photoluminescent material comprises the intermolecular blocking moiety of the photoluminescent compound, wherein the intermolecular blocking moiety comprises at least one of an alkyl chain or a polar group.

24. The method of claim 22, wherein the photoluminescent material comprises a caged intermolecular blocking compound, wherein the caged intermolecular blocking compound comprises at least one of a catenane, a rotaxane, a dendrimer, a nanocarrier, a coordination cage, a metal-organic framework, or a cyclodextrin.

25. The method of claim 24, wherein the caged intermolecular blocking compound comprises the cyclodextrin.

26. The method of claim 21, wherein the photoluminescent compound comprises 4-(5-phenyloxazol-2-yl)phenylpropionic acid (DPOA).

27. The method of claim 21, wherein the substrate comprises a semiconductor wafer.
